(19) United States
(12) Patent Application Publication
(10) Pub. No.: US 2026/0321541 A1
(43) Pub. Date: Oct. 15, 2026

(54) PLASMA PROCESSING APPARATUS AND PLASMA PROCESSING METHOD

(71) Applicant: Hitachi High-Tech Corporation, Minato-ku, Tokyo (JP)

(72) Inventors: Satoru IMAIZUMI, Tokyo (JP); Takahiro ICHIKAWA, Tokyo (JP)

(21) Appl. No.: 18/846,891

(22) PCT Filed: Jul. 12, 2023
(86) PCT No.: PCT/JP2023/025648

§ 371 Date: Sep. 13, 2024

(51) Int. Cl. H01J 37/32; H10P 72/00

(52) U.S. Cl. CPC H01J 37/32146; H10P 72/0421; H01J 2237/334

(57) ABSTRACT

It is an object of the present disclosure to provide a technology allowing for improvement of a processing yield. A device CPU 107 of a plasma processing apparatus 100 adjusts supply of radio frequency power using information indicative of magnitude of the radio frequency power detected during a duration (PA) after predefined time (TMV) has elapsed since either a large amplitude duration PA or a small amplitude duration PB of the radio frequency power started. The device CPU 107 has a function of variably adjust the length of the predefined time (TMV).

### TECHNICAL FIELD

The present disclosure relates to a plasma processing apparatus and a plasma processing method. This disclosure specifically relates to a plasma processing apparatus that includes a processing chamber in a vacuum container and a sample stage for placing a sample such as a semiconductor wafer therein and that processes the sample by forming a plasma in the processing chamber, and relates to a plasma processing apparatus and a plasma processing method for processing the sample by supplying radio frequency power output from a radio frequency power source to an electrode disposed in the sample stage and performing plasma control.

### BACKGROUND ART

Japanese Unexamined Patent Application Publication No. 2014-022482 (Patent Literature 1) has been proposed as a technology for the plasma processing apparatus. Patent Literature 1 discloses a plasma processing apparatus that time modulates radio frequency power and radio frequency bias power for plasma generation.

### CITATION LIST

### Patent Literature

Patent Literature 1: Japanese Unexamined Patent Application Publication No. 2014-022482

### SUMMARY OF INVENTION

### Technical Problem

Described below is a technology considered by the present inventors but not a known technology.

The present inventors considered a technology of time modulating (ON/OFF in a pulsed manner) the radio frequency power output from a radio frequency power source and supplying it to an electrode disposed in a sample stage. In this case, for an output from the radio frequency power source, it is preferable that a travelling wave is detected by a directional coupler built in the radio frequency power source and a feedback (FB) control is performed inside the radio frequency power source so that a peak-to-peak voltage (hereinbelow, referred to as Vpp) that is the output (output range) from the radio frequency power source is constant. As for the feedback control, a problem was found that, due to the characteristics of plasma load, the control is unstable if performed all through the ON duration of the output of the radio frequency power source and the output power from the radio frequency power source is not stabilized. Therefore, the present inventors considered stopping the feedback control in some time domains in the ON duration (or output ON time) of the radio frequency power source, defining a predetermined time when the feedback control is stopped (stop time) as a “mask time value”, and retaining the “mask time value” as a parameter inside the radio frequency power source.

The consideration by the present inventors disclosed that the problem with the above technology was caused by insufficient consideration on the following points. It was found that an optimal value of the “mask time value” for stably controlling the output from the radio frequency power source varies depending on a condition related to the plasma load and the travelling wave power value. Moreover, the “mask time value” can be a fixed value depending on an apparatus specification of the plasma processing apparatus and a manufacturing process of a semiconductor device. However, it was found to be difficult to perform a stable feedback control under all the load conditions if the “mask time value” is fixed, due to expansion of a power output range of the radio frequency power source. That is, with the expansion of the output range of the radio frequency power source, it may become difficult to select a mask time fixed value that satisfies the entire output range.

As described above, the considered technology does not take into consideration the selection of the mask time value that satisfies the entire output power range in relation to the expansion of the output range of the radio frequency power source, and this increases a deviation or offset from a target value of an RF voltage. There was also a problem that a dimension of a shape of a semiconductor wafer used as a sample resulting from a plasma processing deviates from an anticipated dimension, thereby impairing a yield of the processing by the plasma processing apparatus.

It is an object of the present disclosure to provide a technology allowing for improvement of a processing yield (plasma processing apparatus and a plasma processing method). Other problems and novel features will become apparent from the description of this application and accompanying drawings.

### Solution to Problem

A summary of representative embodiments of the present disclosure is briefly described below.

A plasma processing apparatus according to an aspect of the present disclosure includes: a processing chamber arranged inside a vacuum container and inside which a plasma is formed; a sample stage arranged in the processing chamber and on which a semiconductor wafer to be processed with the plasma is placed; an electrode arranged inside the sample stage and to which radio frequency power is supplied during processing of the semiconductor wafer; and a control device that adjusts the supply of the radio frequency power from a radio frequency power source, and the radio frequency power is supplied from the radio frequency power source by repeating a large amplitude duration and a small amplitude duration with respect to each predetermined period during the processing of the semiconductor wafer. The control device adjusts supply of the radio frequency power using information indicative of magnitude of the radio frequency power detected during a corresponding duration after predefined time after either the large amplitude duration or the small amplitude duration started, and has a function of variably adjusting a length of the predefined time.

### Advantageous Effects of Invention

A plasma processing apparatus according to an aspect of the present disclosure can improve a processing yield.

### BRIEF DESCRIPTION OF DRAWINGS

FIG. 1 is a longitudinal section view schematically showing an outline of a configuration of a plasma etching apparatus according to an embodiment;

FIG. 2 is a block diagram of a mask time control according to an embodiment;

FIG. 3 is a diagram conceptionally showing a mask time value used for feedback control of a radio frequency power source;

FIG. 4 is a flowchart illustrating selection of the mask time value of the radio frequency power source by a device

FIG. 5 is an example table illustrating selection of the mask time value of the radio frequency power source by a device CPU;

FIG. 6A is a conceptual diagram of a mask time value fixation according to a comparative example;

FIG. 6B is a conceptual diagram of a mask time value fixation according to a comparative example;

FIG. 7A is a conceptual diagram illustrating selection of the mask time value according to an embodiment; and

FIG. 7B is a conceptual diagram illustrating selection of the mask time value according to an embodiment.

### DESCRIPTION OF EMBODIMENTS

In the following, embodiments are described using drawings. However, in the following description, an identical component is denoted by an identical reference numeral, and description thereof may not be repeated. It should be noted that the drawings are sometimes illustrated schematically compared to its actual aspect, but they show merely an example and does not limit an interpretation of the present disclosure in any way.

### Embodiment

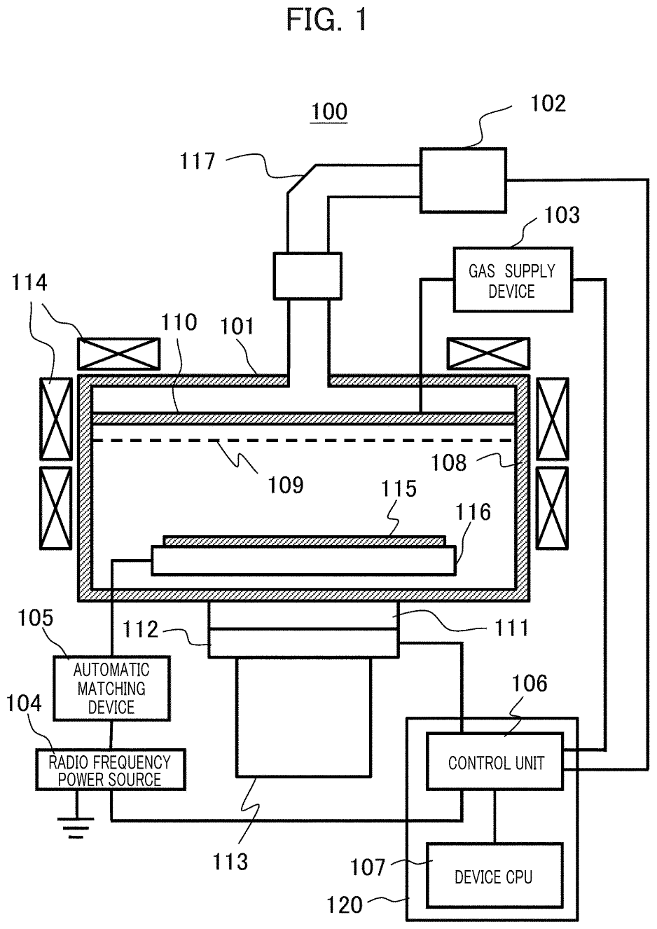

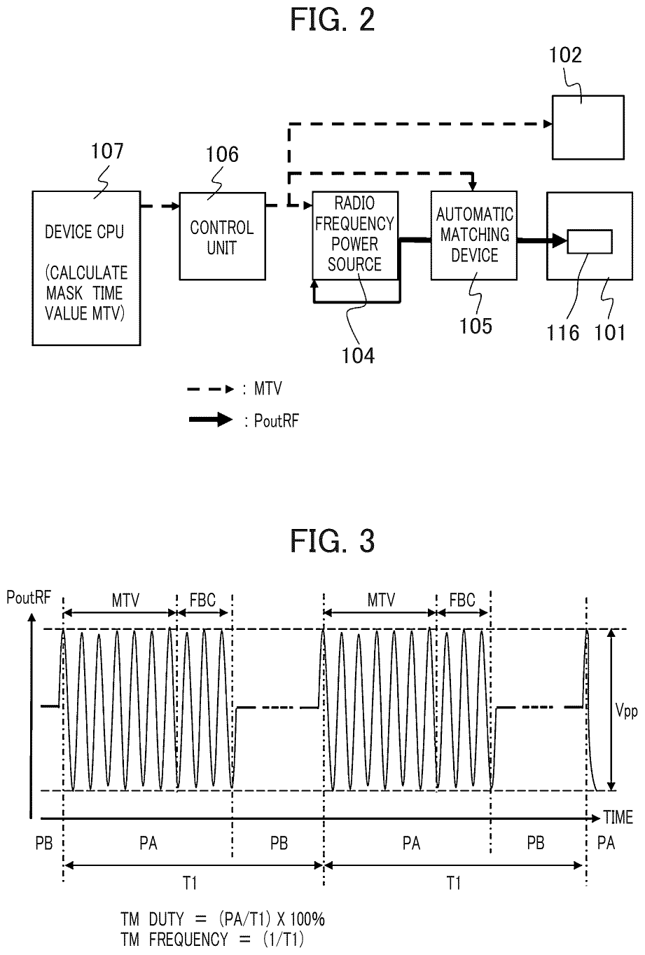

An embodiment of the present disclosure is described below using FIGS. 1 to 7B. FIG. 1 is a longitudinal section view schematically showing an outline of a configuration of a plasma etching apparatus according to an embodiment. FIG. 2 is a block diagram of a mask time control according to an embodiment.

A plasma etching apparatus 100 generates a plasma efficiently by supplying a processing chamber 101 arranged inside a vacuum container 108 with an electric field and a magnetic field for forming a plasma and resonating (Erectron Cyclotron Resonance: ECR) respective movements of electrons derived from the electric field and the magnetic field.

In the same figure, the plasma etching apparatus 100 as a plasma processing apparatus includes the processing chamber 101, an electromagnetic wave supplying unit 102 as an electromagnetic wave supplying device, a gas supply device 103, a radio frequency power source 104 as a radio frequency power source device, an automatic matching device 105 as an automatic matching device circuit, and a control device 120. The control device 120 includes a control unit 106 and a device CPU 107.

The vacuum container 108 that keeps a predefined degree of vacuum is arranged with the processing chamber 101, and includes inside the vacuum container 108 a shower plate 109 for introducing etching gas and a sample placement electrode 116 as a sample stage for placing a semiconductor wafer (also referred to as a sample or a wafer) 115 at a location facing a dielectric window 110 for sealing the vacuum container 108 and the shower plate 109.

Moreover, arranged at a lower part of the processing chamber 101 are an exhaust switching valve 111 that performs exhaust on the vacuum container 108, an exhaust speed variable valve 112, and a vacuum exhaust device 113 that performs exhaust via the exhaust speed variable valve 112. Provided outside the processing chamber 101 are a plurality of magnetic field generating coils 114 forming that form a magnetic field in the processing chamber 101.

The gas supply device 103 is provided for supplying a gas such as an etching gas or an inert gas. The gas supply device 103 supplies the gas into the processing chamber 101 from a gas supply port provided between the dielectric window 110 and the shower plate 109 arranged at an upper part of the vacuum container 108 through the shower plate 109.

In order to propagate an electric field for generating a plasma to the processing chamber 101, a wave guide 117 for propagating an electromagnetic wave is arranged above the processing chamber 101, and the electromagnetic wave oscillated by a magnetron power source 102 serving as a radio frequency power source (Radio Frequency Power Supply) for plasma generation propagates through the wave guide 117, whereby the electric field is supplied to the processing chamber 101. It should be noted that a microwave electromagnetic wave having a frequency of 2.45 GHz, for example, is used in a first embodiment.

The electromagnetic wave falling on the processing chamber 101 via the wave guide 117 acts on the magnetic field excited from the magnetic field generating coil 114 to ionize the etching gas in the processing chamber 101. This ionization generates a high-density plasma.

Furthermore, the radio frequency power source 104 is connected to the sample placement electrode 116 via the automatic matching device 105. A fundamental frequency of the radio frequency power source 104 is, for example, 400 KHz. The automatic matching device 105 changes an impedance between the radio frequency power source 104 and the sample placement electrode 116. The sample placement electrode 116 can be reworded as an electrode arranged inside the sample stage and to which the radio frequency power is supplied from the radio frequency power source 104 during processing of the semiconductor wafer 115.

An etching parameter such as an output, TM Duty, TM frequency, and the like associated with the radio frequency power source 104 and preset to the device CPU 107 is transmitted to the control unit 106 to control an output level of power supply from the radio frequency power source 104. By controlling the output level, the radio frequency power source 104 switches and outputs the output level of the power supply in a predefined periodic pattern. The output power supply is applied to the automatic matching device 105 and the sample placement electrode 116 and forms a bias potential on the wafer 115, thereby attracting charged particles in the plasma to the wafer 115 by virtue of a potential difference between a plasma potential of the generated plasma and the bias potential. The TM duty and the TM frequency will be described later.

As shown in FIG. 2, the device CPU 107 is further configured to be able to switch a mask time set value (also referred to as a mask time value) of the radio frequency power source 104 based on settings of the TM duty, the output power range of the radio frequency power source 104, a gas flow rate to the processing chamber 101, and a pressure range of the processing chamber 101. That is, the device CPU 107 calculates the mask time set value MTV based on the settings of the TM duty, the output power range of the radio frequency power source 104, the gas flow rate to the processing chamber 101, and the pressure range of the processing chamber 101.

The calculated mask time set value MTV is supplied to the control unit 106 and further supplied from the control unit 106 to the radio frequency power source 104. The radio frequency power source 104 is configured to perform feedback control of the radio frequency power (PoutRF) of the radio frequency power source 104 using the received mask time value MTV. The radio frequency power (PoutRF) of the radio frequency power source 104 is configured to be transmitted into a chamber serving as the processing chamber 101 via the automatic matching device 105 and transmitted to the sample placement electrode 116 in the chamber. It should be noted that, in this example, the switching of the mask time set value MTV is also applicable to the magnetron power source 102 (see FIG. 1) and the automatic matching device 105.

Relations between the TM duty, the output of the power supply from the radio frequency power source 104, the periodic pattern, and the processing pressure of the processing chamber 101 and the mask time set value MTV of the radio frequency power source 104 will be described later.

The radio frequency power (PoutRF) provided to the sample placement electrode 116 in this manner acts on the plasma-like etching gas and the wafer 115 to perform a dry etching process on the wafer 115.

It should be noted that the shower plate 109, the sample placement electrode 116, the magnetic field generating coil 114, the exhaust switching valve 111, the exhaust speed variable valve 112, and the wafer 115 are arranged axisymmetrically with respect to a central axis of the processing chamber 101. Thus, radicals and ions generated from the etching gas flow and plasma, as well as reaction products generated by the etching, are introduced coaxially with respect to the wafer and exhausted coaxially. This axisymmetrical flow is effective in improving uniformity of the etching rate and etching shape on the wafer surface.

### Setting of Output From Radio Frequency Power Source 104

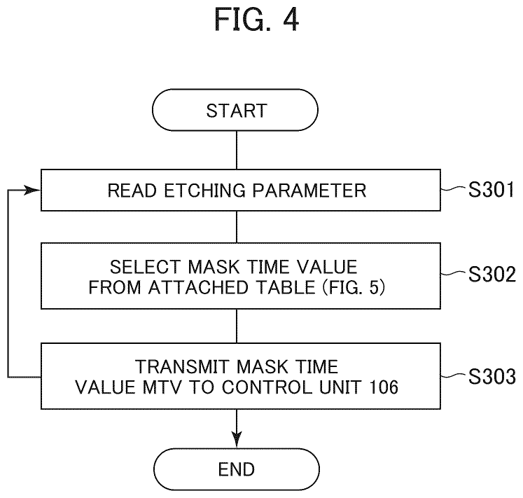

Next, an output control method for the radio frequency power source 104 is described using FIG. 3. FIG. 3 is a diagram conceptionally showing a mask time value used for feedback (FB) control of a radio frequency power source 104. In FIG. 3, Vpp represents a peak-to-peak voltage that is an output (output range) of the radio frequency power source 104.

The radio frequency power PoutRF output from the radio frequency power source 104 is supplied from the radio frequency power source 104 by repeating a large amplitude duration PA of the radio frequency power PoutRF and a small amplitude duration PB of the radio frequency power PoutRF with respect to each predetermined period T1 during the processing of the semiconductor wafer 115. The small amplitude duration PB of the radio frequency power PoutRF can be referred to as a duration in which an amplitude of the radio frequency power PoutRF is 0 (zero) or that is small enough to regard an amplitude of the radio frequency power PoutRF as 0 (zero). The period T1 is also referred to as a predefined periodic pattern.

Moreover, as for the radio frequency output PoutRF of the radio frequency power source 104, a travelling wave is detected by a directional coupler (not shown) built in the radio frequency power source 104, and an FB control FBC is performed in the radio frequency power source 104 so that the travelling wave power is constant. In order to specify timing of the FB control FBC on the output PoutRF of the radio frequency power source 104, a parameter called the mask time value MTV is used.

The mask time value MTV defines a duration (a stop duration of the FB control FBC) in which the FB control FBC is stopped during an ON duration of the output PoutRF of the radio frequency power source 104 (or during the large amplitude duration PA of the radio frequency power PoutRF). The mask time value MTV can be reworded as a predefined time to stop the FB control FBC.

It is desirable to perform the FB control FBC at a timing in which the output set value of the radio frequency power source 104 matches an actual output power value of the radio frequency power source 104. However, the output power of the radio frequency power source 104 changes an output waveform of the radio frequency power source 104 due to an effect of the ON time of the radio frequency power source 104 and the plasma load. Since this changes also changes the timing that the radio frequency power source 104 actually outputs the power value set as the output set value, an optimal timing to be used use for the FB control FBC is changed. If the FB control FBC is not performed at the optimal timing, a waveform out of the output set value of the RF bias power source (radio frequency power source 104), in which the FB control FBC should be stopped in principle, is used for the FB control FBC, preventing an accurate FB control FBC from being performed. This results in a difference between the output set value and the actual output value of the RF bias power source and, when the difference exceeds ±0.5% of the output set value, the difference is significant for performance of the RF bias power source, which is desirably avoided.

Here, the TM duty (also simply referred to as Duty: duty) means a proportion (ratio) of the large amplitude duration PA of the radio frequency power PoutRF with respect to the period T1 (one cycle of period T1). The TM duty can be calculated by (TM duty=(PA/T1)×100%). The TM frequency (TM Frequency) can be represented by (1/T1).

### Operation of Device CPU 107

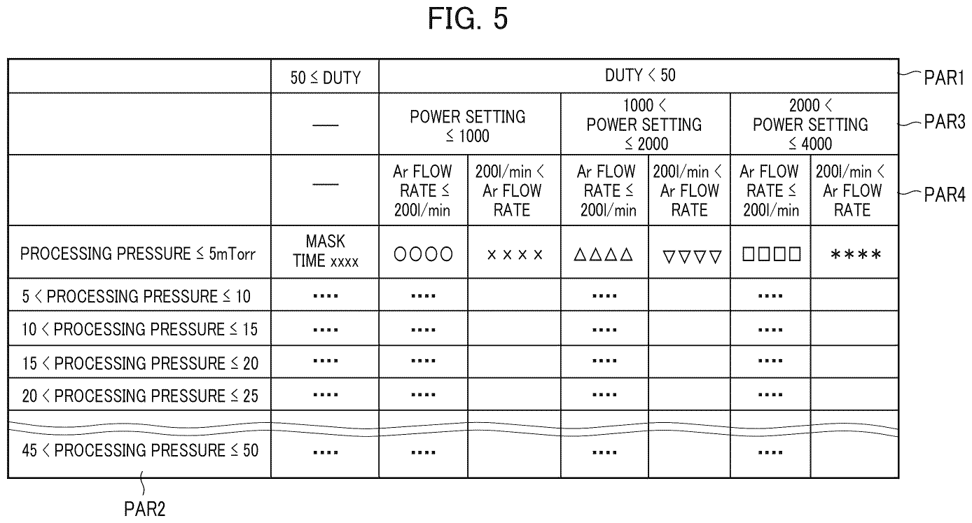

Next, an operation of the flowchart of the device CPU 107 in the control device 120 is described using FIG. 4. FIG. 4 is a flowchart illustrating selection of the mask time value of the radio frequency power source 104 by a device CPU 107. Respective steps S301 to S303 are described herein in the order of the step numbers shown in the figure.

### Step S301

The device CPU 107 obtains the etching parameter associated with a corresponding etching step a predetermined time T4 before the etching step set to the microwave plasma etching apparatus 100. The time T4 is determined taking into consideration delay time for transmitting a set point signal of the plasma processing apparatus 100 and delay time for reflecting a set point signal of the radio frequency power source 104. The device CPU 107 determines the mask time value MTV for setting an output to the radio frequency power source 104 according to the etching parameter. After that, the operation of the device CPU 107 then moves to Step S302.

### Step S302

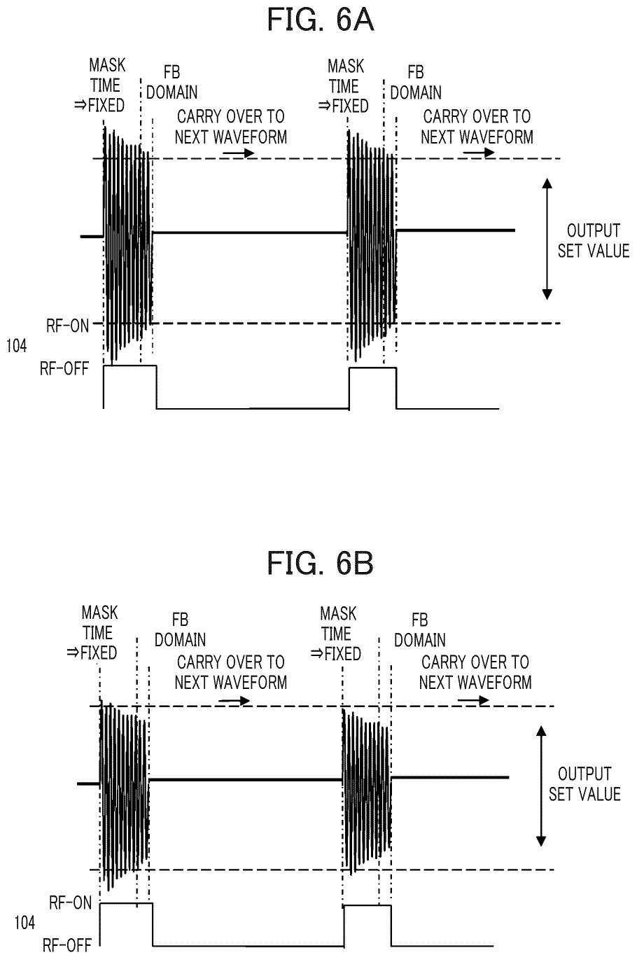

The device CPU 107 selects the mask time value MTV from an attached table. The operation of selecting the mask time value MTV using the attached table will be described later with reference to FIG. 5. After that, the operation of the device CPU 107 then moves to Step S303.

### Step S303

The device CPU 107 transmits the selected mask time value MTV to the control unit 106 at Step 303.

Here, if the current etching step is the final etching step, the device CPU 107 terminates the operation of the flowchart. If the current etching step is not the final etching step, the device CPU 107 moves its operation to Step 301 with reference to the etching parameter of the corresponding next etching step the predetermined time T4 before the input next etching step. In other words, the flowchart in FIG. 4 is characterized by making the mask time value MTV variable with respect to each etching step. That is, making the mask time value MTV variable means variably adjusting the length of the predefined time to stop the FB control FBC.

That is, the plasma processing apparatus 100 can be outlined as following. The plasma processing apparatus 100 includes the processing chamber 101 arranged inside the vacuum container 108 and inside which a plasma is formed, the sample stage 116 arranged in the processing chamber 101 and on which the semiconductor wafer 115 to be processed with the plasma is placed, the electrode (116) arranged inside the sample stage 116 and to which the radio frequency power is supplied during the processing of the semiconductor wafer 115, and the control device 120 (106, 107) that adjusts the supply of the radio frequency power from the radio frequency power source 104.

And then, the plasma processing apparatus 100 is configured such that the radio frequency power is supplied from the radio frequency power source 104 by repeating the large amplitude duration PA and the small amplitude duration PB with respect to each predetermined period T1 during the processing of the semiconductor wafer 115.

The device CPU 107 of the control device 120 adjusts (FB control FBC) the supply of the radio frequency power using information indicative of magnitude of the radio frequency power detected during a duration (in FIG. 3, corresponding to the duration denoted with FB control FBC) after a predefined time (in FIG. 3, corresponding to the mask time value MTV) has elapsed since either the large amplitude duration PA or the small amplitude duration PB of the radio frequency power (in FIG. 3, corresponding to the large amplitude duration PA) started (information about detection result of the travelling wave by the directional coupler). The device CPU 107 of the control device 120 is configured to have a function of variably adjusting the length of the predefined time (in FIG. 3, the mask time value MTV).

The plasma processing method using the plasma processing apparatus 100 can be outlined as following., That is, the plasma processing method is a plasma processing method of processing the semiconductor wafer 115 using a plasma by placing the semiconductor wafer 115 to be processed on the sample stage 116 arranged inside the processing chamber 101 arranged inside the vacuum container 108 and inside which the plasma is formed, while supplying the electrode (116) arranged inside the sample stage 115 with the radio frequency power from the radio frequency power source 104 during the processing of the semiconductor wafer.

The method is configured so that the radio frequency power is supplied from the radio frequency power source 104 by repeating the large amplitude duration PA and the small amplitude duration PB with respect to each predetermined period T1. Furthermore, the power supply is adjusted using information indicative of magnitude of the radio frequency power detected during a duration (in FIG. 3, corresponding to the duration denoted with FB control FBC) after a predefined time (in FIG. 3, corresponding to the mask time value MTV) has elapsed since either the large amplitude duration PA or the small amplitude duration PB of the radio frequency power (in FIG. 3, corresponding to the large amplitude duration PA) started (information about detection result of the travelling wave by the directional coupler), and the length of the predefined time (in FIG. 3, corresponding to the mask time value MTV) is variably adjusted.

FIG. 5 is an example table illustrating selection of the mask time value of the radio frequency power source 104 by a device CPU 107. Each parameter in FIG. 5 (parameter 1 (PAR1), parameter 2 (PAR2), parameter 3 (PAR3), and parameter 4 (PAR41)) is determined by the condition actually used in the etching process. The optimal mask time value MTV varies depending on the maximum outputtable power of the radio frequency power source 104 installed. Therefore, when installing the radio frequency power source 104 in the etching apparatus 100, the optimal mask time value MTV is measured in advance for a combination of respective parameters such as the TM duty, the output power range, the gas flow rate, the processing pressure range, and the like, and input to and stored in the device CPU 107 as a table in advance before introducing the flowchart of automatic selection of the mask time value MTV according to the disclosure. The condition for the advance measurement is described taking an example of FIG. 5. Parameters 1-4 used for the etching process are, for example, the following.
parameter 1 (PAR1): TM Duty=(PA/T1)×100%:
   1) 50% or more,
   2) 50% or less (minimum pulse width).
parameter 2 (PAR2): processing pressure range (processing pressure) during etching process in the processing chamber 101:
   1) 5 mTorr or less,
   2) above 5 mTorr and 10 mTorr or less,
   3) above 10 mTorr and 15 mTorr less,
   4) above 15 mTorr and 20 mTorr or less,
   5) above 20 mTorr and 25 mTorr or less,
   . . . ,
   N) above 45 mTorr and 50 mTorr or less,
parameter 3 (PAR3): output power range (power setting) of radio frequency power PoutRF output by the radio frequency power source 104:
   1) 1000 W or less,
   2) above 1000 W and 2000 W or less,
   3) above 2000 W and 4000 W or less.
parameter 4 (PAR4): gas flow rate or argon (Ar) gas during etching process:
   1) 200 ml/min or less,
   2) above 200 ml/min.

The mask time value MTV is changed in units of 10% under the condition of each combination of these parameters 1-4. The mask time value MTV is actually measured and recorded into the table shown in FIG. 5 when an actual value closest to the output power range set for the parameter 3 (PAR3) is obtained. This enables the automatic selection of the mask time value MTV by using the recorded table shown in FIG. 5.

Measuring the table shown in FIG. 5 in advance and storing it in the device CPU 107 makes it possible to perform the FB control without being affected by the parameters 1-4 (TM duty, output power range, gas flow rate, processing pressure range) and keep the difference between the output set value and the actual output value of the radio frequency power source 104 within a predefined tolerance.

The device CPU 107 reads data in the table shown in FIG. 5 at the time of operation in Step S301 and automatically selects the mask time value MTV by matching with each of the input etching parameters 1-4 including the TM duty, the output power range, the gas flow rate, and the processing pressure range.

That is, the technology of the present disclosure is configured so that the length of the predefined time (mask time value MTV) is adjusted according to the condition of processing the semiconductor wafer using the table (data) shown in FIG. 5 indicative of the relation between at least one value selected from a plurality of parameters including the pressure in the processing chamber 101 during the processing of the semiconductor wafer, the magnitude of the radio frequency power (PoutRF) output from the radio frequency power source 104, and the proportion of the large amplitude duration PA or the small amplitude duration PB in the period T1 (herein, TM duty) and the predefined period (mask time value MTV). Furthermore, this embodiment is configured so that the automatic selection of the mask time value MTV is enabled. Moreover, in a plurality of processes constituting a single processing of the semiconductor wafer performed in the processing chamber 101, the length of the predefined time (mask time value MTV) is adjusted according to the condition of processing in each process.

Not only the above-described parameters 1-4 but also other parameters such as the electric power of the magnetron power source 102, the output frequency of the radio frequency power source 104, the TM frequency set to the radio frequency power source 104, the electric current applied to the magnetic field generating coil 114, and the temperature of the sample placement electrode 116 can be added to or deleted in FIG. 5.

The data in the table shown in FIG. 5 can not only be stored in the device CPU 107 but also be directly input to a computer PC installed in the device CPU 107 and reflected as needed by communicating between the computer PC and the device CPU 107.

With a series of operations described above, the device CPU 107 can transmit the optimal mask time value MTV set to the radio frequency power source 104 via the control unit 106 with respect to a plurality of etching steps.

### Effect of Embodiments

The embodiments have the following effects.

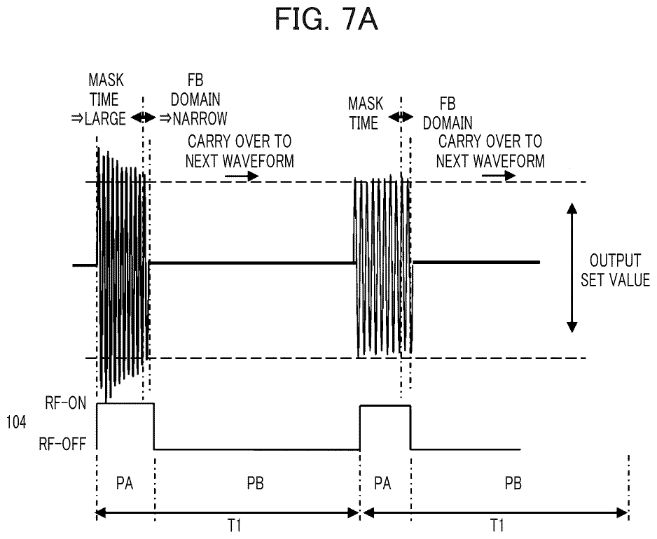

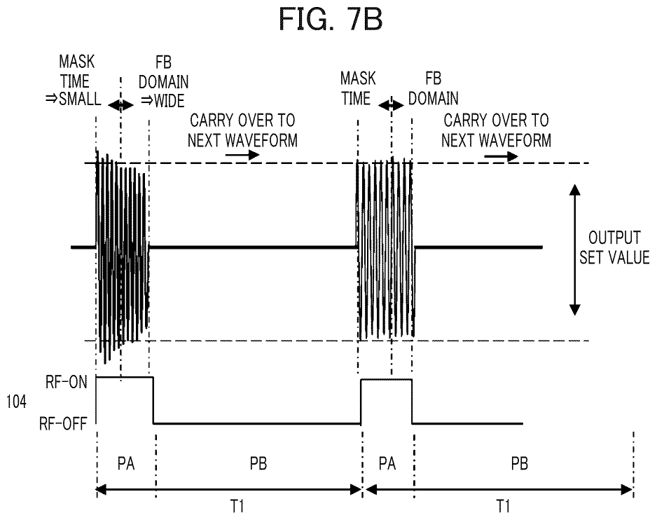

FIGS. 6A, 6B, 7A, and 7B are conceptual diagrams of waveforms output from the radio frequency power source 104. These waveforms are conceivable examples, and such a waveform as shown in FIGS. 6A, 6B, 7A, or 7B is not necessarily output from the radio frequency power source 104.

The timing of the FB control while power is being output from the radio frequency power source 104 changes its optimal value due to effects of the radio frequency output power, the ON time, and the plasma load.

FIGS. 6A and 6B are conceptual diagrams of a mask time value fixation according to a comparative example. FIGS. 7A and 7B are conceptual diagrams of the mask time value selection (variable) according to an embodiment.

The difference between FIGS. 6A and 6B is that the rise of the waveform output from the radio frequency power source 104 is changed due to the effects of the radio frequency output power, the ON time, and the plasma load. When the FB domain is controlled to be constant, as described above, the FB control is not performed with the optimal value, and a waveform deviating from the output set value of the RF bias power source that is the period in which the FB control should be stopped in principle is used for the FB control. Therefore, there is a risk that the actual output power different from the output set value may be output from the radio frequency power source 104.

As shown in FIGS. 7A and 7B contrary to FIGS. 6A and 6B, by selecting an appropriate mask time value MTV when the output waveform of the radio frequency power source 104 changes due to the TM duty, the output power range, and the processing pressure range, the timing at which the output set value and the actual output power value get close to each other can be used for the FB control FBC. As a result, the radio frequency power source 104 can recognize a value close to the output set value and perform an operation of outputting the next waveform.

As described above, the operation of selecting the mask time value MTV from the etching parameters including the TM duty, the output power range, and the processing pressure range can achieve reduction of offset between the output set value and the actual output of the radio frequency power source 104.

In this disclosure, the mask time value MTV of the radio frequency power source 104 can be set variably with respect to each processing step, and the mask time value MTV is set variably depending on the condition in relation to the output and the plasma load of the radio frequency power source 104 set on its recipe at the start time of the processing step of the wafer 115. Moreover, an appropriate mask time value MTV is automatically set using the data obtained in advance indicative of the relation between the condition in relation to the output and the plasma load of the radio frequency power source 104 obtained in advance and the mask time value MTV as a parameter table (see FIG. 5).

This makes it possible to set the optimal mask time value MTV to the radio frequency power source 104 with respect to each processing step of the wafer 115. It is thus possible to achieve a stable plasma processing (etching process). It is also possible to improve a yield of the plasma processing (etching process).

As described above, a problem is solved that a dimension of a shape of a wafer resulting from a processing deviates from an anticipated dimension, thereby impairing a yield of the processing by the plasma processing apparatus.

### LIST OF REFERENCE SIGNS

100: plasma etching apparatus (plasma processing apparatus)
101: processing chamber
104: radio frequency power source
106: control unit
107: device CPU
108: vacuum container
115: semiconductor wafer (sample)
116: sample placement electrode (sample stage)
120: control device

1. A plasma processing apparatus comprising:
a processing chamber arranged inside a vacuum container and inside which a plasma is formed; a sample stage arranged in the processing chamber and on which a semiconductor wafer to be processed with the plasma is placed; an electrode arranged inside the sample stage and to which radio frequency power is supplied during processing of the semiconductor wafer; and a control device that adjusts the supply of the radio frequency power from a radio frequency power source,
wherein the radio frequency power is supplied from the radio frequency power source by repeating a large amplitude duration and a small amplitude duration with respect to each predetermined period during the processing of the semiconductor wafer, and
wherein the control device adjusts supply of the radio frequency power using information indicative of magnitude of the radio frequency power detected during a corresponding duration after predefined time has elapsed since either the large amplitude duration or the small amplitude duration started, and has a function of variably adjusting a length of the predefined time.

2. The plasma processing apparatus according to claim 1,
wherein the length of the predefined time is adjusted using data indicative of a relation between at least one value selected from a plurality of parameters including a pressure in the processing chamber during the processing of the semiconductor wafer, a magnitude of the radio frequency power output from the radio frequency power source, and a proportion of the large amplitude duration or the small amplitude duration in the period and the predefined period.

3. The plasma processing apparatus according to claim 1,
wherein the radio frequency power is supplied by repeating the large amplitude duration and a duration in which an amplitude is 0 or is small enough to be regarded as 0 with respect to each period.

4. The plasma processing apparatus according to claim 1,
wherein the length of predefined time is adjusted according to a condition of processing the semiconductor wafer.

5. The plasma processing apparatus according to claim 4,
wherein the length of the predefined time is adjusted according to a condition of the processing in a plurality of processes constituting a single processing of the semiconductor wafer performed in the processing chamber.

6. A plasma processing method of processing a semiconductor wafer using a plasma by placing the semiconductor wafer to be processed on a sample stage arranged in a processing chamber arranged inside a vacuum container and inside which the plasma is formed, while supplying an electrode arranged inside the sample stage with radio frequency power from a radio frequency power source during the processing of the semiconductor wafer,
wherein the radio frequency power is supplied from the radio frequency power source by repeating a large amplitude duration and a small amplitude duration with respect to each predetermined period and adjusted using information indicative of magnitude of the radio frequency power detected during a corresponding duration after predefined time has elapsed since either the large amplitude duration or the small amplitude duration started, and
wherein the length of the predefined time is variably adjusted.

7. The plasma processing method according to claim 6,
wherein the length of the predefined time is adjusted using data indicative of a relation between at least one parameter value selected from a plurality of parameters including a pressure in the processing chamber during the processing of the semiconductor wafer, a magnitude of the radio frequency power output from the radio frequency power source, and a proportion of the large amplitude duration or the small amplitude duration in the period and the predefined period.

8. The plasma processing method according to claim 6,
wherein the radio frequency power is supplied by repeating the large amplitude duration and a duration in which an amplitude is 0 or is small enough to be regarded as 0 with respect to each period.

9. The plasma processing method according to claim 6,
wherein the length of predefined time is adjusted according to a condition of processing the semiconductor wafer.

10. The plasma processing method according to claim 9,
wherein the length of the predefined time is adjusted according to a condition of the processing in a plurality of processes constituting a single processing of the semiconductor wafer performed in the processing chamber.
